(19) United States
(12) Patent Application Publication
(10) Pub. No.: US 2025/0337214 A1
(43) Pub. Date: Oct. 30, 2025

(54) SEMICONDUCTOR LASER PACKAGES AND MODULES

(71) Applicant: ANHUI GAN SEMICONDUCTOR CO., LTD., Lu'an (CN)

(72) Inventors: Jinjian ZHENG, Lu'an (CN); Shuiqing LI, Lu'an (CN); Heqing DENG, Lu'an (CN); Feilin XUN, Lu'an (CN); Jiangyong ZHANG, Lu'an (CN); Xin CAI, Lu'an (CN); Jiabin LAN, Lu'an (CN); Xiaoqin LI, Lu'an (CN); Zhiyong HU, Lu'an (CN); Wanjun CHEN, Lu'an (CN)

(73) Assignee: ANHUI GAN SEMICONDUCTOR CO., LTD., Lu'an (CN)

(21) Appl. No.: 18/657,742

(22) Filed: May 7, 2024

Related U.S. Application Data
(63) Continuation-in-part of application No. PCT/CN2024/089762, filed on Apr. 25, 2024.

(51) Int. Cl. H01S 5/02212; H01S 5/02325; H01S 5/024

(52) U.S. Cl. CPC H01S 5/02212; H01S 5/02325; H01S 5/02469

(57) ABSTRACT

The present disclosure provides a semiconductor laser package and module. The package and module include a pin, a tube holder, a tube tongue, a heat sink, and a laser. A packaging form includes at least one of a plastic-encapsulated package and module, a transistor outline can (TO-CAN)-type package and module, and a chip-on-submount (COS) package and module. The package and module have a thermal conductance gradient. A thermal conductance of the tube holder is a, a thermal conductance of the tube tongue is b, a thermal conductance of the heat sink is c, and a thermal conductance of the laser is d, wherein the thermal conductance gradient is one of d≤a≤b≤c, d≤a≤c≤b, a≤d≤b≤c, or a≤d≤c≤b.

### CROSS-REFERENCE TO RELATED APPLICATIONS

This application is a continuation-in-part of International Application No. PCT/CN2024/089762 filed on Apr. 25, 2024, the entire contents of which are incorporated herein by reference.

### TECHNICAL FIELD

The present disclosure relates to the field of semiconductor optoelectronic devices, and in particular, to a semiconductor laser package and module.

### BACKGROUND

Lasers are widely used in laser displays, laser TVs, laser projectors, communications, medical applications, weaponry, guidance systems, range finding, spectral analysis, cutting, precision welding, high-density optical storage, etc. There are various types of lasers, including solid, gas, liquid, semiconductor, dye lasers, etc. Compared with other types of lasers, all-solid-state semiconductor lasers have the advantages of small size, high efficiency, light weight, good stability, long life, simple and compact structure, and miniaturization. Devices with the same function as the lasers include semiconductor light-emitting diodes such as nitride semiconductor light-emitting diodes. However, there are significant differences between the lasers and the nitride semiconductor light-emitting diodes. Firstly, lasers are generated by carriers undergoing stimulated radiation, resulting in a smaller spectral half-width, high brightness, and single laser output power reaching the watt level, while nitride semiconductor light-emitting diodes exhibit spontaneous radiation with an output power at the milliwatt level. Secondly, the current density used in the lasers can reach up to KA/cm2, which is more than 2 orders of magnitude higher than that in nitride light-emitting diodes, leading to stronger electron leakage, more serious Oshie recombination, stronger polarization effects, and more severe electron-hole mismatch, resulting in a more significant efficiency decay Droop effect. Thirdly, light-emitting diodes exhibit spontaneous lepton radiation without external action, producing incoherent light from high-energy level to low-energy level leaps, while the lasers exhibit stimulated lepton radiation, with the induced photon energy being equal to the difference in energy levels of the electron jump, resulting in fully coherent light between the photon and the induced photon. Lastly, the lasers and the nitride semiconductor light-emitting diodesd opertate under different principles: light-emitting diodes operate under the influence of an external voltage, causing electron-hole jumps to the active layer or the p-n junction for radiation composite luminescence, while the lasers require stimulation conditions to be met before lasing, including the necessity to fulfill the carrier inversion distribution in the active zone for stimulated radiation light to oscillate back and forth within the resonant cavity, propagate in the gain medium for light amplification, and meet the threshold conditions for the gain to exceed the loss, and ultimately output laser.

### SUMMARY

In response to the above problem, the object of the present disclosure is to provide a semiconductor laser package and module. By designing a plurality of parameter gradients and values between various components in the semiconductor laser package and module, the thermal conductivity uniformity and thermal stress distribution uniformity of the semiconductor laser can be improved, thereby obtaining a semiconductor laser package and module with better performance and longer life.

One or more embodiments of the present disclosure provide a semiconductor laser package and module. The package and module may include a pin, a tube holder, a tube tongue, a heat sink, and a laser. A packaging form may include at least one of a plastic-encapsulated package and module, a transistor outline can (TO-CAN)-type package and module, and a chip-on-submount (COS) package and module. The package and module may have a thermal conductance gradient. A thermal conductance of the tube holder may be a, a thermal conductance of the tube tongue may be b, a thermal conductance of the heat sink may be c, and a thermal conductance of the laser may be d, wherein the thermal conductance gradient may be one of d≤a≤b≤c, d≤a≤c≤b, a≤d≤b≤c, or a≤d≤c≤b.

One or more embodiments of the present disclosure provide a semiconductor laser package and module, the package and module further include a tube cap, a tube housing, and a zener tube. Materials of the tube tongue, the tube holder, the tube cap, and the tube housing may include any one or a combination of Cu, Al, Ag, Au, chromium, nickel, C, stainless steel, Pd, Ti, Zr, Ta, Nb, V, Hf, Ga, Fe, Si, P, Cu plated with Ni, Cu plated with Pd, Cu plated with Ni/Pd, Fe plated with Ni, Fe plated with Pd, Fe plated with Ni/Pd, iron-clad copper plated with Ni, iron-clad copper plated with Pd, iron-clad copper plated with Ni/Pd, Cu plated with Pd/Ni, Fe plated with Pd/Ni, iron-clad copper plated with Pd/Ni, Kovar plated with Pd, Kovar plated with Ni, Kovar plated with Ni/Pd, Kovar plated with Pd/Ni, CuW, BeO, Kovar, Fe, Cu—Fe—Cu composite material, Cu—Fe composite material, Cu—Al composite material, or iron-clad copper.

One or more embodiments of the present disclosure provide a semiconductor laser package and module. A material of the heat sink may include any one or a combination of SiC, Cu—SiC composite structure, Cu—SiC—AuSn, Cu—SiC—Cu composite structure, Cu—AlN composite structure, Cu—AlN—Cu composite structure, Cu—AlN—AuSn, AuSn, AlN, diamond, Cu-diamond composite structure, Cu-diamond-Cu composite structure, Cu-diamond-AuSn composite structure, AlN single-sided copper clad, AlN double-sided copper clad, SiC single-sided copper clad, SiC double-sided copper clad, diamond single-sided copper clad, diamond double-sided copper clad, Ti, Zr, Ta, Nb, V, Hf, AlN/Zr/Cu composite structure, AlN/Ta/Cu composite structure, AlN/Nb/Cu composite structure, AlN/V/Cu composite structure, AlN/Hf/Cu composite structure, AlN/Zr/Nb/Cu composite structure, AlN/Nb/V/Cu composite structure, Si, CuW, TiW, Cu, BeO, GaN, GaAs, InP, and Mo; the laser includes at least one of a gallium nitride-based laser, a gallium arsenide-based laser, an indium phosphorus-based laser, an aluminum nitride-based laser, and an InGaN-based laser. A wavelength of the laser may be in a range of 200 nm to 3000 nm.

One or more embodiments of the present disclosure provide a semiconductor laser package and module. The thermal conductance of the tube holder may be in a range of 50 to 500 W/(m*K), the thermal conductance of the tube tongue may be in a range of 100 to 600 W/(m*K), the thermal conductance of the heat sink may be in a range of 130 to 5000 W/(m*K), and the thermal conductance of the laser may be in a range of 20 to 300 W/(m*K).

One or more embodiments of the present disclosure provide a semiconductor laser package and module. The package and module may have a thermal resistance coefficient gradient. The thermal resistance coefficient of the tube holder may be e, a thermal resistance coefficient of the tube tongue may be f, a thermal resistance coefficient of the heat sink may be g, and a thermal resistance coefficient of the laser may be h, wherein the thermal resistance coefficient gradient may be one of g≤f≤e≤h, g≤f≤h≤e, f≤g≤e≤h, or f≤g≤h≤e.

One or more embodiments of the present disclosure provide a semiconductor laser package and module. The package and module may have a relative dielectric constant gradient. A relative dielectric constant of the tube holder may be j, a relative dielectric constant of the tube tongue may be k, a relative dielectric constant of the heat sink may be m, a relative dielectric constant of the laser may be n, wherein the relative dielectric constant gradient may be one of k≤j≤m≤n, j≤k≤m≤n, k≤j≤n≤m, or j≤k≤n≤m.

One or more embodiments of the present disclosure provide a semiconductor laser package and module. The package and module may have a high-frequency dielectric constant gradient. A high-frequency dielectric constant of the tube holder may be p, a high-frequency dielectric constant of the tube tongue may be q, a high-frequency dielectric constant of the heat sink may be r, a high-frequency dielectric constant of the laser may be s, wherein the high-frequency dielectric constant gradient may be one of q≤p≤r≤s, p≤q≤r≤s, q≤p≤s≤r, or p≤q≤s≤r.

One or more embodiments of the present disclosure provide a semiconductor laser package and module. The package and module may have a thermal expansion coefficient gradient. A thermal expansion coefficient of the tube holder may be t, a thermal expansion coefficient of the tube tongue may be u, a thermal expansion coefficient of the heat sink may be v, and a thermal expansion coefficient of the laser may be w, wherein v≤w≤t≤u. A thermal expansion coefficient of the tube holder may be in a range of 510 to 6 to 1510-6/K, a thermal expansion coefficient of the tube tongue may be in a range of 810-6 to 2010-6/K, a thermal expansion coefficient of the heat sink may be in a range of 0.510-6 to 810-6/K, and a thermal expansion coefficient of the laser may be in a range of 1.510-6 to 1510-6/K.

One or more embodiments of the present disclosure provide a semiconductor laser package and module. The laser may include a laser chip, a longitudinal acoustic velocity of the laser chip may not be greater than a longitudinal acoustic velocity of the tube tongue, and the longitudinal acoustic velocity of the laser chip may not be greater than a longitudinal acoustic velocity of the heat sink. A transverse acoustic velocity of the laser chip may not be greater than a transverse acoustic velocity of the tube tongue, and the transverse acoustic velocity of the laser chip may not be greater than a transverse acoustic velocity of the heat sink. A thermal conductivity of the laser chip may not be greater than the thermal conductivity of the tube tongue, and the thermal conductivity of the laser chip may not be greater than the thermal conductivity of the heat sink. An absorption coefficient of the laser chip may not be greater than an absorption coefficient of the tube tongue, and an absorption coefficient of the laser chip may not be greater than an absorption coefficient of the heat sink.

One or more embodiments of the present disclosure provide a semiconductor laser package and module. An electron mobility of a laser chip may not be less than an electron mobility of the tube tongue, and the electron mobility of the laser chip may not be less than an electron mobility of the heat sink. A hole mobility of the laser chip may not be less than a hole mobility of the tube tongue, and the hole mobility of the laser chip may not be less than a hole mobility of the heat sink. An electron diffusion constant of the laser chip may not be less than an electron diffusion constant of the tube tongue, and the electron diffusion constant of the laser chip may not be less than an electron diffusion constant of the heat sink. A hole diffusion coefficient of the laser chip may not be less than a hole diffusion coefficient of the tube tongue, and the hole diffusion coefficient of the laser chip may not be less than a hole diffusion coefficient of the heat sink.

One or more embodiments of the present disclosure provide a semiconductor laser package and module. An elastic modulus of a laser chip may not be less than an clastic modulus of the tube tongue, and the clastic modulus of the laser chip may not be greater than an elastic modulus of the heat sink. The clastic modulus of the tube tongue may be in a range of 50 to 250 GPa, the clastic modulus of the laser chip may be in a range of 100 to 400 GPa, and the clastic modulus of the heat sink may be in a range of 250 to 1000 Gpa.

One or more embodiments of the present disclosure provide a semiconductor laser package and module. A breakdown field strength of a laser chip may not be less than a breakdown field strength of the heat sink. A static dielectric constant of the laser chip may not be less than a static dielectric constant of the heat sink. An electron drift velocity of the laser chip may not be less than an electron drift velocity of the heat sink. A linear diffusion coefficient of the laser chip may not be greater than a linear diffusion coefficient of the heat sink, and the linear diffusion coefficient of the laser chip may not be less than a linear diffusion coefficient of the tube tongue. A density of the tube tongue may not be less than a density of the laser chip, and the density of the laser chip may not be less than a density of the heat sink. An intrinsic carrier concentration of the laser chip may not be less than an intrinsic carrier concentration of the heat sink.

The embodiments of the present disclosure include at least the following beneficial effects: (1) the thermal conductance gradient and the thermal resistance coefficient gradient of the semiconductor laser package and module are designed to form a uniform thermal conductivity channel, which reduces bottleneck points, improves a uniformity of the thermal conductivity of the laser package and module, improves a heat dissipation performance and a heat conduction efficiency, reduces a heat accumulation and a junction temperature increase of the laser, and decreases a temperature of an active layer of the laser chip and a temperature increase rate, thus improving issues such as red shift of the wavelength of the laser, power drop, increased threshold current, etc.; (2) the thermal expansion coefficient gradient, the relative dielectric constant gradient and the high-frequency dielectric constant gradient of the semiconductor laser package and module are designed to enhance a uniformity of a temperature distribution and a uniformity of the thermal expansion coefficient of the laser and enhance a uniformity of a thermal expansion and thermal stress distribution, thus improving issues such as temperature quenching, catastrophic optical damage (COD), laser fracture, aging dead lamp, etc., reducing the thermal lensing effect and the stress birefringence effect, improving depolarization and distortion of laser beams, and enhancing the quality of far-field FFP image and a beam quality factor of the laser; (3) the longitudinal acoustic velocity, the transverse acoustic velocity, the thermal conductivity, and the absorption coefficient of the laser chip, the tube tongue, and the heat sink of the semiconductor laser package and module are designed to enhance a group velocity of low-frequency phonons, a phonon transport efficiency of lattice vibration, a Kink distortion current value of a Power-Current curve of the laser and a current value of a saturated laser power, and a high-current and high-power driving performance of the laser; (4) the electron mobility, the hole mobility, the electron diffusion constant, and a hole diffusion constant of the laser chip, the tube tongue, and the heat sink of the semiconductor laser package and module are designed to enhance a photon degeneracy and accelerate an excited radiation over a spontaneous radiation, reduce an increase in a threshold current of the laser in an aging process, reduce a relaxation time of a laser module, reduce a probability of phonon scattering, and improve a thermal degradation of the laser and a proportion of aging leakage; (5) the elasticity modulus, the density, and the linear diffusion coefficient of the tube tongue, the heat sink, and the laser chip of the semiconductor laser package and module are designed to improve strain matching degrees of the tube tongue, the heat sink and the laser chip, reduce a ratio of laser fracture and a ratio of gold wire detachment, and reduce an abnormal ratio of heat sink shedding, blistering, and warping; and (6) the static dielectric constant, the breakdown field strength, the electron drift velocity, and the intrinsic carrier concentration of the tube tongue, the heat sink, and the laser chip of the semiconductor laser package and module are designed to improve an electro-static discharge (ESD) resistance capability of the laser module.

### BRIEF DESCRIPTION OF THE DRAWINGS

The present disclosure is further illustrated in terms of exemplary embodiments. These exemplary embodiments are described in detail with reference to according to the drawings. These embodiments are non-limiting exemplary embodiments, in which like reference numerals represent similar structures, and wherein:

FIG. 1 is a schematic diagram illustrating an exemplary structure of a semiconductor laser package and module according to some embodiments of the present disclosure;

FIG. 2 is a schematic diagram illustrating an exemplary structure of a semiconductor laser package and module according to some embodiments of the present disclosure; and

FIG. 3 is a schematic diagram illustrating an exemplary structure of a semiconductor laser package and module according to some embodiments of the present disclosure.

### DETAILED DESCRIPTION

To more clearly illustrate the technical solutions related to the embodiments of the present disclosure, a brief introduction of the drawings referred to the description of the embodiments is provided below. The accompanying drawings do not represent the entirety of the embodiments.

It should be understood that “system”, “device”, “unit” and/or “module” as used herein is a manner used to distinguish different components, elements, parts, sections, or assemblies at different levels. However, if other words serve the same purpose, the words may be replaced by other expressions.

Some embodiments of the present disclosure provide a semiconductor laser package and module that includes a pin, a tube holder, a tube tongue, a heat sink, and a laser.

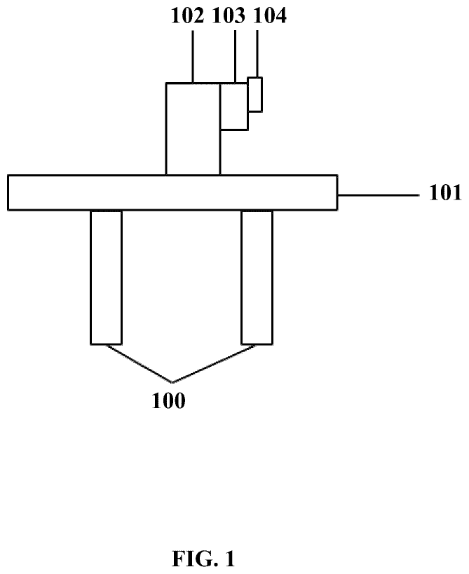

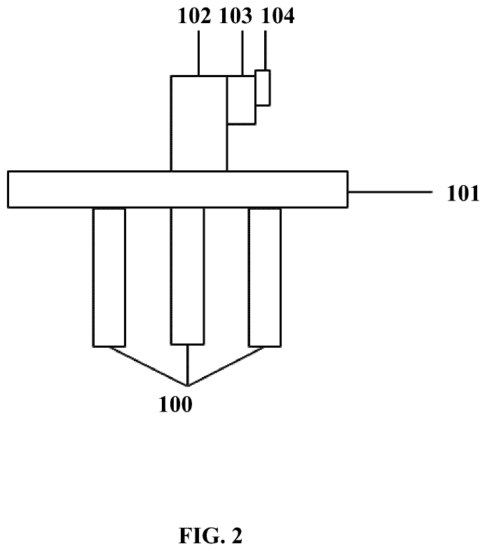

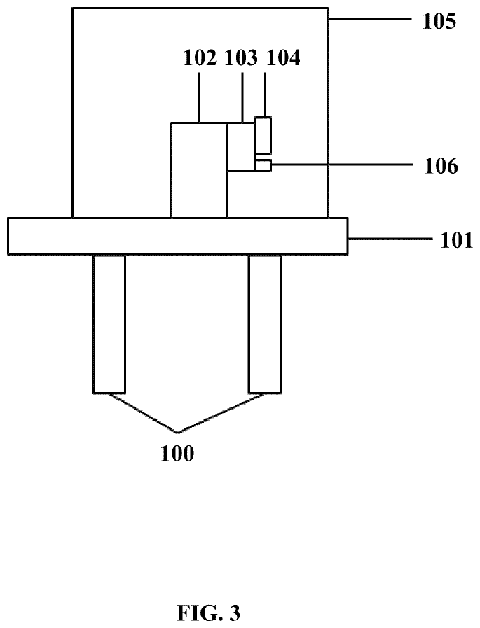

FIG. 1 is a schematic diagram illustrating an exemplary structure of a semiconductor laser package and module according to some embodiments of the present disclosure; FIG. 2 is a schematic diagram illustrating an exemplary structure of a semiconductor laser package and module according to some embodiments of the present disclosure; and FIG. 3 is a schematic diagram illustrating an exemplary structure of a semiconductor laser package and module according to some embodiments of the present disclosure.

In some embodiments, as shown in FIG. 1 and FIG. 2, the semiconductor laser package and module (also referred to as the package and module hereinafter) includes a pin 100, a tube holder 101, a tube tongue 102, a heat sink 103, and a laser 104.

In some embodiments, a packaging form of the package and module may include at least one of a plastic-encapsulated package and module, a transistor outline can (TO-CAN)-type package and module, and a chip-on-submount (COS) package and module.

The pin 100 is configured to connect internal and peripheral circuits of the integrated circuit. In some embodiments, the package and module may be connected to the peripheral circuit via the pin 100 to receive and/or output signals or data, or to obtain electrical power.

In some embodiments, the pin 100 may be located on a side surface of the tube holder 101. In some embodiments, the pin 100 may be connected to the tube holder 101 by any feasible connection. For example, the connection manner may be soldering, bonding, or the like.

In some embodiments, a material of pin 100 may include a metal, an alloy, or the like. For example, the material of pin 100 may be silver-plated copper wire or tin-plated copper wire.

In some embodiments, the pin 100 may have a plurality of forms. For example, the pin 100 may be any of a two-pin or a three-pin. Merely by way of example, the pin 100 shown in FIG. 1 is a two-pin configuration, and the pin 100 shown in FIG. 2 is a three-pin configuration.

The tube holder 101 is configured to fix the tube tongue 102 and the pin 100. In some embodiments, the tube tongue 102 may also be connected to the tube holder 101 by any feasible connection. For example, the connection manner may be welding, bonding, etc.

The tube tongue 102 is configured to fix the heat sink 103 with the laser 104. In some embodiments, the tube tongue 102 may be provided on another side surface of the tube holder 101. In some embodiments, the pin 100 and the tube tongue 102 may be provided on separate surfaces on different sides of the tube holder 101.

In some embodiments, the tube tongue 102 may be connected to the heat sink 103 by any feasible connection manner. For example, the connection manner may be welding, bonding, or the like.

The tube holder 101 and the tube tongue 102 may be of a plurality of materials. In some embodiments, the materials of the tube holder 101 and the tube tongue 102 may include any one or a combination of Cu, Al, Ag, Au, chromium, nickel, C, stainless steel, Pd, Ti, Zr, Ta, Nb, V, Hf, Ga, Fc, Si, P, Cu plated with Ni, Cu plated with Pd, Cu plated with Ni/Pd, Fe plated with Ni, Fe plated with Pd, Fe plated with Ni/Pd, iron-clad copper plated with Ni, iron-clad copper plated with Pd, iron-clad copper plated with Ni/Pd, Cu plated with Pd/Ni, Fe plated with Pd/Ni, iron-clad copper plated with Pd/Ni, Kovar plated with Pd, Kovar plated with Ni, Kovar plated with Ni/Pd, Kovar plated with Pd/Ni, CuW, BcO, Kovar, Fc, Cu—Fe—Cu composite material, Cu-Fc composite material, Cu—Al composite material, or iron-clad copper.

The heat sink 103 is configured to help dissipate or transfer heat from the laser. In some embodiments, the heat sink 103 may be disposed between the tube tongue 102 and the laser 104 to prevent heat from transferring to the tube tongue 102 and causing damage to the tube tongue 102.

The heat sink 103 may be of a plurality of materials. In some embodiments, the material of the heat sink 103 may include any one or a combination of SiC, Cu—SiC composite structure, Cu—SiC—AuSn, Cu—SiC—Cu composite structure, Cu—AlN composite structure, Cu—AlN—Cu composite structure, Cu—AlN—AuSn, AuSn, AlN, diamond, Cu-diamond composite structure, Cu-diamond-Cu composite structure, Cu-diamond-AuSn composite structure, AlN single-sided copper clad, AlN double-sided copper clad, SiC single-sided copper clad, SiC double-sided copper clad, diamond single-sided copper clad, diamond double-sided copper clad, Ti, Zr, Ta, Nb, V, Hf, AlN/Zr/Cu composite structure, AlN/Ta/Cu composite structure, AlN/Nb/Cu composite structure, AlN/V/Cu composite structure, AlN/Hf/Cu composite structure, AlN/Zr/Nb/Cu composite structure, AlN/Nb/V/Cu composite structure, Si, CuW, TiW, Cu, BcO, GaN, GaAs, InP, and Mo.

A packaged semiconductor laser applying the heat sink 103 made of one or more of the materials described above may effectively enhance heat dissipation capability, reduce thermal resistance, increase laser output power, and prolong life of the laser.

The laser 104 is configured to emit a laser light. The laser 104 includes a laser chip. The laser chip is configured to convert electrical energy into laser energy.

In some embodiments, the laser 104 may be conencted to the tube tongue 102 via the heat sink 103.

In some embodiments, the laser 104 may include at least one of a gallium nitride-based laser, a gallium arsenide-based laser, an indium phosphorus-based laser, an aluminum nitride-based laser, and an InGaN-based laser.

In some embodiments, a wavelength of the laser 104 may be in a range of 200 nm to 3000 nm. In some embodiments, the wavelength of the laser 104 may be in a range of 300 nm to 3000 nm. In some embodiments, the wavelength of the laser 104 may be in a range of 500 nm to 2700 nm. In some embodiments, the wavelength of the laser 104 may be in a range of 700 nm to 2500 nm. In some embodiments, the wavelength of the laser 104 may be in a range of 1000 nm to 2300 nm. In some embodiments, the wavelength of the laser 104 may be in a range of 1200 nm to 2100 nm.

In some embodiments, as shown in FIG. 3, the package and module may also include a tube cap (not shown in the figure), a tube housing 105, and a zener tube 106.

The tube housing 105 is configured to enclose and protect the tube tongue 102, the heat sink 103, the zener tube 106, and the laser 104. In some embodiments, the tube housing 105 may be fixed to a surface on the tube holder on the same side as the tube tongue 102 by any feasible attachment manner. For example, the attachment manner may be welding, bonding, etc.

The tube cap is configured to seal the tube housing 105. In some embodiments, the tube cap may be sleeved around the periphery of the tube housing 105 and connected to the tube holder 100 by any feasible connection manner. For example, the connection manner may be welding, bonding, etc.

The zener tube 106 is configured to stabilize a voltage of the laser. In some embodiments, the zener tube 106 may be disposed on a side of the heat sink 103 away from the tube tongue 102 by any feasible connection manner. For example, the connection manner may be welding, bonding, etc.

The tube cap and the tube housing 105 may be of a plurality of materials. In some embodiments, the material of the tube cap and the tube housing 105 may include any one or a combination of Cu, Al, Ag, Au, chromium, nickel, C, stainless steel, Pd, Ti, Zr, Ta, Nb, V, Hf, Ga, Fe, Si, P, Cu plated with Ni, Cu plated with Pd, Cu plated with Ni/Pd, Fe plated with Ni, Fe plated with Pd, Fe plated with Ni/Pd, iron-clad copper plated with Ni, iron-clad copper plated with Pd, iron-clad copper plated with Ni/Pd, Cu plated with Pd/Ni, Fe plated with Pd/Ni, iron-clad copper plated with Pd/Ni, Kovar plated with Pd, Kovar plated with Ni, Kovar plated with Ni/Pd, Kovar plated with Pd/Ni, CuW, BcO, Kovar, Fe, Cu—Fe—Cu composite material, Cu-Fc composite material, Cu—Al composite material, or iron-clad copper.

In some embodiments, the package and module have a thermal conductance gradient. The thermal conductance gradient may characterize a change rate of the thermal conductance of the components in the package and module.

In some embodiments, a thermal conductance of the tube holder 101 is a, a thermal conductance of the tube tongue 102 is b, a thermal conductance of the heat sink 103 is c, a thermal conductance of the laser 104 is d, and a thermal conductance gradient may be one of d≤a≤b≤c, d≤a≤c≤b, a≤d≤b≤c, or a≤d≤c≤b.

In some embodiments, the thermal conductance of the tube holder 101 may be in a range of 50 to 500 W/(m*K), the thermal conductance of the tube tongue 102 may be in a range of 100 to 600 W/(m*K), the thermal conductance of the heat sink 103 may be in a range of 130 to 5000 W/(m*K), and the thermal conductance of the laser 104 may be in a range of 20 to 300 W/(m*K).

In some embodiments, the package and module have a thermal resistance coefficient gradient. The thermal resistance coefficient gradient may characterize a change rate of the thermal resistance coefficient of the components in the package and module.

In some embodiments, the thermal resistance coefficient of the tube holder 101 is e, the thermal resistance coefficient of the tube tongue 102 is f, the thermal resistance coefficient of the heat sink 103 is g, and the thermal resistance coefficient of the laser 104 is h, and the thermal resistance coefficient gradient may be one of g≤f≤e≤h, g≤f≤h≤e, f≤g≤e≤h, or f≤g≤h≤e.

Thermal losses may cause thermal expansion and uneven distribution of thermal stresses, resulting in temperature quenching, laser fracture, thermal lensing effect, and stress birefringence effect. At the same time, there is a significant amount of heat generated in the active region of the laser chip due to non-radiative recombination loss and free carrier absorption, and the epitaxial and the material of the chip have resistance, resulting in Joule thermal loss and carrier absorption loss under current injection. The material of the chip has low thermal conductivity and poor heat dissipation performance, resulting in increased temperature in the active layer of the chip, causing red shift in the excitation wavelength, decreased quantum efficiency, lowered power, increased threshold current, shortened life, decreased reliability, etc.

In some embodiments of the present disclosure, by designing the thermal conductance gradient and the thermal resistance coefficient gradient of the semiconductor laser package and module, a uniform thermal conductivity channel may be formed, which reduces bottleneck points, improves a uniformity of the thermal conductivity of the laser package and module, improves a heat dissipation performance and a heat conduction efficiency, reduces a heat accumulation and a junction temperature increase of the laser, and decreases a temperature of an active layer of the laser chip and a temperature increase rate, thus improving issues such as red shift of the wavelength of the laser, power drop, increased threshold current, etc., thus effectively reducing an optical degradation of the laser from 20% to 60% down to 2% to 20% over a 10000-hour aging period.

The heat loss is a conversion of the Stokes frequency shift loss formed by the photon energy difference between the pump light and the oscillating light to heat, and a conversion of the energy loss of a coupling rate from the pump energy level to the upper energy level of the laser that is not 1 to heat. Both conversions generate a large amount of waste heat, which may cause uneven temperature distribution of the laser, resulting in uneven thermal expansion and distribution of thermal stresses and generating temperature quenching, laser fracture, thermal lensing effect, and stress birefringence effect. The thermal lensing effect refers to a generation of a lens-like phenomenon in space, while the stress birefringence effect may change the polarization state of the incident light, depolarizing and distorting the laser beam.

In some embodiments, the package and module have a relative dielectric constant gradient. The relative dielectric constant gradient may characterize a change rate of the relative dielectric constant of the components in the package and module.

In some embodiments, a relative dielectric constant of the tube holder 101 is j, a relative dielectric constant of the tube tongue 102 is k, a relative dielectric constant of the heat sink 103 is m, a relative dielectric constant of the laser 104 is n, and the relative dielectric constant gradient may be one of k≤j≤m≤n, j≤k≤m≤n, k≤j≤n≤m, or j≤k≤n≤m.

In some embodiments, the package and module have a high-frequency dielectric constant gradient. The high-frequency dielectric constant gradient may characterize a change rate of the high-frequency dielectric constant of the components in the package and module.

In some embodiments, a high-frequency dielectric constant of the tube holder 101 is p, a high-frequency dielectric constant of the tube tongue 102 is q, a high-frequency dielectric constant of the heat sink 103 is r, a high-frequency dielectric constant of the laser 104 is s, and the high-frequency dielectric constant gradient may be one of q≤p≤r≤s, p≤q≤r≤s, q≤p≤s≤r, or p≤q≤s≤r.

In some embodiments, the package and module have a thermal expansion coefficient gradient. The thermal expansion coefficient gradient may characterize a change rate of the thermal expansion coefficient of the components in the package and module.

In some embodiments, a thermal expansion coefficient of the tube holder 101 is t, a thermal expansion coefficient of the tube tongue 102 is u, a thermal expansion coefficient of the heat sink 103 is v, a thermal expansion coefficient of the laser 104 is w, and the the thermal expansion coefficient gradient may be v≤w≤t≤u.

In some embodiments, the thermal expansion coefficient of the tube holder 101 may be in a range of 5*10-6 to 15*10-6/K, the thermal expansion coefficient of the tube tongue 102 may be in a range of 8*10-6 to 20*10-6/K, the thermal expansion coefficient of the heat sink 103 may be in a range of 0.5*10-6 to 8*10-6/K, and the thermal expansion coefficient of the laser 104 may be in a range of 1.5*10-6 to 15*10-6/K.

In some embodiments of the present disclosure, by designing the thermal expansion coefficient gradient, the relative dielectric constant gradient and the high-frequency dielectric constant gradient of the semiconductor laser package and module, a uniformity of a temperature distribution and a uniformity of the thermal expansion coefficient of the laser may be enhanced, and a uniformity of a thermal expansion and thermal stress distribution may be enhanced, thus improving issues such as temperature quenching, catastrophic optical damage (COD), laser fracture, aging and dead lamp, etc., reducing the thermal lensing effect and the stress birefringence effect, improving depolarization and distortion of laser beams, and enhancing the quality of far-field FFP image and a beam quality factor of the laser.

In some embodiments, a longitudinal acoustic velocity of the laser chip is not greater than a longitudinal acoustic velocity of the tube tongue 102, and the longitudinal acoustic velocity of the laser chip is not greater than a longitudinal acoustic velocity of the heat sink 103. The longitudinal acoustic velocity refers to a propagation velovity of longitudinal waves in a sound wave.

In some embodiments, a transverse acoustic velocity of the laser chip is not greater than a transverse acoustic velocity of the tube tongue 102, and the transverse acoustic velocity of the laser chip is not greater than a transverse acoustic velocity of the heat sink 103. The transverse acoustic velocity refers to a propagation velocity of transverse waves in a sound wave.

In some embodiments, a thermal conductivity of the laser chip is not greater than a thermal conductivity of the tube tongue 102, and the thermal conductivity of the laser chip is not greater than a thermal conductivity of the heat sink 103. The thermal conductivity may characterize an ability to propagate heat.

In some embodiments, an absorption coefficient of the laser chip is not greater than an absorption coefficient of the heat sink 102, and the absorption coefficient of the laser chip is not greater than an absorption coefficient of the heat sink 103. The absorption coefficient may characterize an ability to absorb light.

As the lasers are used at high current densities, a large amount of non-radiative composite heat is generated, which causes issues such as a relatively low kink distortion current value of a Power-Current curve of the laser and a relatively low current value of a saturated laser power, thermal degradation, excessive aging leakage, etc.

In some embodiments of the present disclosure, by designing the longitudinal acoustic velocity, the transverse acoustic velocity, the thermal conductivity and the absorption coefficient of the laser chip, the tube tongue and the heat sink of the semiconductor laser package and module, a group velocity of low-frequency phonons may be enhanced, a phonon transport efficiency of lattice vibration may be increased, the Kink distortion current value of the Power-Current curve of the laser and the current value of the saturated laser power may be increased, and a high-current and high-power driving performance of the laser may be enhanced.

In some embodiments, an electron mobility of the laser chip is not less than an electron mobility of the tube tongue 102, and the electron mobility of the laser chip is not less than an electron mobility of the heat sink 103. The electron mobility may characterize a velovity of electrons move in response to an electric field.

In some embodiments, a hole mobility of the laser chip is not less than a hole mobility of the tube tongue 102, and the hole mobility of the laser chip is not less than a hole mobility of the heat sink 103. The hole mobility may characterize a velocity at which holes move in response to an electric field.

In some embodiments, an electron diffusion constant of the laser chip is not less than an electron diffusion constant of the tube tongue 102, and the electron diffusion constant of the laser chip is not less than an electron diffusion constant of the heat sink 103. The electron diffusion constant may characterize a degree of electrons diffusing in a substance.

In some embodiments, a hole diffusion coefficient of the laser chip is not less than a hole diffusion coefficient of the tube tongue 102, and the hole diffusion coefficient of the laser chip is not less than a hole diffusion coefficient of the heat sink 103. The hole diffusion coefficient may characterize a degree of hole diffusing in a substance.

In some embodiments of the present disclosure, by designing the electron mobility, the hole mobility, the electron diffusion constant, and the hole diffusion coefficient of the laser chip, the tube tongue, and the heat sink of the laser package and module, a photon degeneracy may be increased and an excited radiation may be accelerated over a spontaneous radiation, an increase in a threshold current of the laser in an aging process may be reduced, an increase in the 10000H aging threshold current may decrease from 50˜80% to 10˜40%, a relaxation time of a laser module may be reduced, a probability of phonon scattering may be reduced, a thermal degradation of the laser and a proportion of aging leakage may be improved, and the 10000H aging leakage may decrease from +/−1˜5 uA to +/−0˜1 uA.

In some embodiments, an elastic modulus of the laser chip is not less than an elastic modulus of the tube tongue 102, and the elastic modulus of the laser chip is not greater than an elastic modulus of the heat sink 103.

In some embodiments, the elastic modulus of the tube tongue 102 may be in a range of 50 to 250 GPa, the elastic modulus of the laser chip may be in a range of 100 to 400 GPa, and the clastic modulus of the heat sink 103 may be in a range of 250 to 1000 GPa.

As the lasers are used at high currents and high current density, a large amount of heat is generated. Further, poor heat dissipation of the device and poor temperature characteristics may exacerbate stress mismatches in the semiconductor laser chip, the heat sink, and the tube tongue. Problems such as laser fracture, gold wire fracture, gold wire detachment, heat sink detachment, blistering, warping, etc., may occur while an electro-static discharge (ESD) resistance capability of a laser module is relatively weak.

In some embodiments of the present disclosure, by designing the elastic modulus, the density, and the linear diffusion coefficient of the tube tongue, the heat sink, and the laser chip of the laser module, strain matching degrees of the tube tongue, the heat sink, and the laser chip may be increased, a ratio of laser fracture, a ratio of gold wire fracture, and a ratio of gold wire detachment may be reduced, an abnormal ratio of gold wire fracture and an abnormal ratio of gold wire detachment may be reduced from 57 PPM to 7 PPM, and an abnormal ratio of heat sink shedding, blistering, and warping may be reduced from 32 PPM to 5 PPM.

In some embodiments, a breakdown field strength of the laser chip is not less than 103 of a breakdown field strength of the heat sink.

In some embodiments, a static dielectric constant of the laser chip is not less than 103 of a static dielectric constant of the heat sink. The static dielectric constant may characterize the response of a substance to an electric field.

In some embodiments, an electron drift velocity of the laser chip is not less than 103 of an electron drift velocity of the heat sink. The electron drift velocity refers to an average velocity at which electrons move through a conductor in the presence of the electric field.

In some embodiments, a linear diffusion coefficient of the laser chip is not greater than of a linear diffusion coefficient of the heat sink 103, and the linear diffusion coefficient of the laser chip is no less than a linear diffusion coefficient of the tube tongue 102.

In some embodiments, a density of the tube tongue 102 is not less than a density of the laser chip, and the density of the laser chip is not less than a density of the heat sink 103.

In some embodiments, an intrinsic carrier concentration of the laser chip is not less than an intrinsic carrier concentration of the heat sink 103.

In some embodiments of the present disclosure, by designing the static dielectric constant, the breakdown field strength, the electron drift velocity, and the intrinsic carrier concentration of the tube tongue, the heat sink, the laser chip of the laser module, the ESD resistance capability of the laser module may be improved, and a human body model (HBM) ESD may be increased from a pass rate of over 90% at 50-200V to over 90% at 200-2 KV.

The following table compares the performance of the laser in some embodiments of the present disclosure with a conventional laser:

| | Conven- | The laser | |
|---|---|---|---|
| | tional | of the present | Variation |
| Item | laser | disclosure | magnitude |
| Optical catastrophe ratio (PPM) | 22 | 4 | −82% |
| 10000 H aging light decay | 29% | 7% | −76% |
| Aggregate spot resolution (nm) | >200 | <20 | |
| Beam quality factor M2 | 2.3 | 1.24 | −46% |
| 10000 H aging dead lamp (PPM) | 87 | 7 | −92% |

In some embodiments of the present disclosure, by designing a plurality of coefficient gradients and constant gradients of the semiconductor laser package and module and parameters of the components, the semiconductor laser package and module with better performance and longer life may be obtained.

In addition, some features, structures, or characteristics of one or more embodiments in the present disclosure may be properly combined.

In some embodiments, the numbers expressing quantities or properties used to describe and claim certain embodiments of the present disclosure are to be understood as being modified in some instances by the term “about,” “approximate,” or “substantially.” For example, “about,” “approximate” or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the present disclosure are approximations, the numerical values set forth in the specific examples are reported as precisely as practicable.

In the event of any inconsistency or conflict between the descriptions, definitions, and/or the use of terms in the materials cited in this disclosure and those described in this disclosure, the descriptions, definitions, and/or the use of terms in this disclosure shall prevail.

What is claimed is:

1. A semiconductor laser package and module, wherein the package and module include a pin, a tube holder, a tube tongue, a heat sink, and a laser;
a packaging form includes at least one of a plastic-encapsulated package and module, a transistor outline can (TO-CAN)-type package and module, and a chip-on-submount (COS) package and module;
the package and module have a thermal conductance gradient, a thermal conductance of the tube holder being a, a thermal conductance of the tube tongue being b, a thermal conductance of the heat sink being c, and a thermal conductance of the laser being d, wherein the thermal conductance gradient is one of d≤a≤b≤c, d≤a≤c≤b, a≤d≤b≤c, or a≤d≤c≤b.

2. The package and module of claim 1, wherein the package and module further include a tube cap, a tube housing, and a zener tube;
materials of the tube tongue, the tube holder, the tube cap, and the tube housing include any one or a combination of Cu, Al, Ag, Au, chromium, nickel, C, stainless steel, Pd, Ti, Zr, Ta, Nb, V, Hf, Ga, Fe, Si, P, Cu plated with Ni, Cu plated with Pd, Cu plated with Ni/Pd, Fe plated with Ni, Fe plated with Pd, Fe plated with Ni/Pd, iron-clad copper plated with Ni, iron-clad copper plated with Pd, iron-clad copper plated with Ni/Pd, Cu plated with Pd/Ni, Fe plated with Pd/Ni, iron-clad copper plated with Pd/Ni, Kovar plated with Pd, Kovar plated with Ni, Kovar plated with Ni/Pd, Kovar plated with Pd/Ni, CuW, BeO, Kovar, Fe, Cu—Fe—Cu composite material, Cu—Fe composite material, Cu—Al composite material, or iron-clad copper.

3. The package and module of claim 1, wherein a material of the heat sink includes any one or a combination of SiC, Cu—SiC composite structure, Cu—SiC—AuSn, Cu—SiC—Cu composite structure, Cu—AlN composite structure, Cu—AlN—Cu composite structure, Cu—AlN—AuSn, AuSn, AlN, diamond, Cu-diamond composite structure, Cu-diamond-Cu composite structure, Cu-diamond-AuSn composite structure, AlN single-sided copper clad, AlN double-sided copper clad, SiC single-sided copper clad, SiC double-sided copper clad, diamond single-sided copper clad, diamond double-sided copper clad, Ti, Zr, Ta, Nb, V, Hf, AlN/Zr/Cu composite structure, AlN/Ta/Cu composite structure, AlN/Nb/Cu composite structure, AlN/V/Cu composite structure, AlN/Hf/Cu composite structure, AlN/Zr/Nb/Cu composite structure, AlN/Nb/V/Cu composite structure, Si, CuW, TiW, Cu, BeO, GaN, GaAs, InP, and Mo;
the laser includes at least one of a gallium nitride-based laser, a gallium arsenide-based laser, an indium phosphorus-based laser, an aluminum nitride-based laser, and an InGaN-based laser; and
a wavelength of the laser is in a range of 200 nm to 3000 nm.

4. The package and module of claim 1, wherein the thermal conductance of the tube holder is in a range of 50 to 500 W/(m*K), the thermal conductance of the tube tongue is in a range of 100 to 600 W/(m*K), the thermal conductance of the heat sink is in a range of 130 to 5000 W/(m*K), and the thermal conductance of the laser is in a range of 20 to 300 W/(m*K).

5. The package and module of claim 1, wherein the package and module have a thermal resistance coefficient gradient, a thermal resistance coefficient of the tube holder being e, a thermal resistance coefficient of the tube tongue being f, a thermal resistance coefficient of the heat sink being g, a thermal resistance coefficient of the laser being h, wherein the thermal resistance coefficient gradient is one of g≤f≤e≤h, g≤f≤h≤e, f≤g≤e≤h, or f≤g≤h≤e.

6. The package and module of claim 1, wherein the package and module have a relative dielectric constant gradient, a relative dielectric constant of the tube holder being j, a relative dielectric constant of the tube tongue being k, a relative dielectric constant of the heat sink being m, a relative dielectric constant of the laser being n, wherein the relative dielectric constant gradient is one of k≤j≤m≤n, j≤k≤m≤n, k≤j≤n≤m, or j≤k≤n≤m.

7. The package and module of claim 1, wherein the package and module have a high-frequency dielectric constant gradient, a high-frequency dielectric constant of the tube holder being p, a high-frequency dielectric constant of the tube tongue being q, a high-frequency dielectric constant of the heat sink being r, a high-frequency dielectric constant of the laser being s, wherein the high-frequency dielectric constant gradient is one of q≤p≤r≤s, p≤q≤r≤s, q≤p≤s≤r, or p≤q≤s≤r.

8. The package and module of claim 1, wherein the package and module have a thermal expansion coefficient gradient, a thermal expansion coefficient of the tube holder being t, a thermal expansion coefficient of the tube tongue being u, a thermal expansion coefficient of the heat sink being v, and a thermal expansion coefficient of the laser being w, wherein: v≤w≤t≤u; and
a thermal expansion coefficient of the tube holder is in a range of 510 to 6 to 1510-6/K, a thermal expansion coefficient of the tube tongue is in a range of 810-6 to 2010-6/K, a thermal expansion coefficient of the heat sink is in a range of 0.510-6 to 810-6/K, and a thermal expansion coefficient of the laser is in a range of 1.510-6 to 1510-6/K.

9. The package and module of claim 1, wherein the laser includes a laser chip, a longitudinal acoustic velocity of the laser chip is not greater than a longitudinal acoustic velocity of the tube tongue, and the longitudinal acoustic velocity of the laser chip is not greater than a longitudinal acoustic velocity of the heat sink;
a transverse acoustic velocity of the laser chip is not greater than a transverse acoustic velocity of the tube tongue, and the transverse acoustic velocity of the laser chip is not greater than a transverse acoustic velocity of the heat sink;
a thermal conductivity of the laser chip is not greater than the thermal conductivity of the tube tongue, and the thermal conductivity of the laser chip is not greater than the thermal conductivity of the heat sink; and
an absorption coefficient of the laser chip is not greater than an absorption coefficient of the tube tongue, and an absorption coefficient of the laser chip is not greater than an absorption coefficient of the heat sink.

10. The package and module of claim 1, wherein an electron mobility of a laser chip is not less than an electron mobility of the tube tongue, and the electron mobility of the laser chip is not less than an electron mobility of the heat sink;
a hole mobility of the laser chip is not less than a hole mobility of the tube tongue, and the hole mobility of the laser chip is not less than a hole mobility of the heat sink;
an electron diffusion constant of the laser chip is not less than an electron diffusion constant of the tube tongue, and the electron diffusion constant of the laser chip is not less than an electron diffusion constant of the heat sink; and
a hole diffusion coefficient of the laser chip is not less than a hole diffusion coefficient of the tube tongue, and the hole diffusion coefficient of the laser chip is not less than a hole diffusion coefficient of the heat sink.

11. The package and module of claim 1, wherein an elastic modulus of a laser chip is not less than an elastic modulus of the tube tongue, and the elastic modulus of the laser chip is not greater than an elastic modulus of the heat sink; and
the elastic modulus of the tube tongue is in a range of 50 to 250 GPa, the elastic modulus of the laser chip is in a range of 100 to 400 GPa, and the elastic modulus of the heat sink is in a range of 250 to 1000 Gpa.

12. The package and module of claim 1, wherein a breakdown field strength of a laser chip is not less than a breakdown field strength of the heat sink;
a static dielectric constant of the laser chip is not less than a static dielectric constant of the heat sink;
an electron drift velocity of the laser chip is not less than an electron drift velocity of the heat sink;
a linear diffusion coefficient of the laser chip is not greater than a linear diffusion coefficient of the heat sink, and the linear diffusion coefficient of the laser chip is not less than a linear diffusion coefficient of the tube tongue;
a density of the tube tongue is not less than a density of the laser chip, and the density of the laser chip is not less than a density of the heat sink; and
an intrinsic carrier concentration of the laser chip is not less than an intrinsic carrier concentration of the heat sink.
